(19) United States
(12) Patent Application Publication
(10) Pub. No.: US 2025/0220985 A1
(43) Pub. Date: Jul. 3, 2025

(54) INTEGRATED CIRCUIT

(71) Applicant: Taiwan-Asia Semiconductor Corporation, Hsinchu City (TW)

(72) Inventors: Wen-Tsung LAI, Hsinchu City (TW); Kun-De LIN, Hsinchu City (TW)

(21) Appl. No.: 18/883,081

(22) Filed: Sep. 12, 2024

(30) Foreign Application Priority Data
Dec. 27, 2023 (TW) 112151166

(51) Int. Cl. H01L 29/06; H01L 27/088; H01L 29/78

(52) U.S. Cl. CPC H10D 62/107; H10D 84/83; H10D 30/60

(57) ABSTRACT

An integrated circuit is provided. The integrated circuit includes a transistor array and a guard ring. The guard ring is formed on a periphery of the transistor array. The guard ring includes a plurality of ring regions, and each of the ring regions includes a doped area. A doped area of an inner side of the ring regions is greater than a doped area of an outer side of the ring regions.

### CROSS-REFERENCES TO RELATED APPLICATIONS

This application claims the benefit of priority to Taiwanese Patent Application No. 112151166 filed on Dec. 27, 2023, which is hereby incorporated by reference in its entirety.

### BACKGROUND OF THE INVENTION

### Field of the Invention

The present invention relates to an integrated circuit and, more particularly to an integrated circuit with multiple guard rings disposed on the periphery of a transistor array.

### Descriptions of the Related Art

When manufacturing Metal-Oxide-Semiconductor Field-Effect Transistor (MOSFET) arrays, a common issue with the MOSFET arrays is insufficient withstand voltage capability, especially when used in high-voltage applications. This problem may lead to defects in electrical interconnects or withstand voltage between MOSFETs, thereby reducing the performance and reliability of the components.

To address the issue of insufficient withstand voltage, the current approach often involves increasing the number of MOSFETs in the MOSFET array to achieve the required withstand voltage for the overall circuit. However, increasing the number of MOSFETs simultaneously significantly raises the manufacturing cost of the entire circuit.

In view of this, the present invention proposes an integrated circuit design that is cost-effective and can greatly enhance the withstand voltage of the circuit.

### SUMMARY OF THE INVENTION

The objective of the present invention is to provide an integrated circuit with high withstand voltage. This is achieved by disposing a plurality of ring regions on the periphery of the transistor array, with each of the ring regions having a certain proportion of doped area. When a surge occurs during circuit operation, the surge current can be diverted outward through the ring regions. This way can prevent the high current and the high voltage of the surge from damaging the transistor array, and the withstand voltage of the transistor array in the circuit can be significantly increased to 1500 volts or more.

To achieve the above objective, the present invention discloses an integrated circuit comprising a transistor array and a guard ring. The guard ring is formed on the periphery of the transistor array. The guard ring includes a plurality of ring regions, each of the ring regions has a doped area. The doped area of an inner side of the ring regions is greater than the doped area of an outer side of the ring regions.

In one embodiment, the doped area of an innermost side of the ring regions is equal to a total area of the innermost side of the ring regions.

In one embodiment, the ratio of a side length of the transistor array to a total width of the ring regions is less than 10.

In one embodiment, the ratio of the side length to the total width is 5:3.

In one embodiment, the ring regions are divided into an inner part and an outer part, and the width of the inner part is larger than 100 micrometers (μm).

In one embodiment, an undoped area of the inner part of the ring regions and the doped area of the outer part of the ring regions are formed by a plurality of discrete parts, and the shape of each of the discrete parts is one of a rectangle, a circle, and a polygon.

In one embodiment, when the number of the ring regions is one, a withstand voltage of the transistor array is improved by 20% to 50%.

In one embodiment, the withstand voltage of the transistor array is improved with the increase of the total width.

In one embodiment, the doped area of each of the ring regions is provided with a ring shape.

In one embodiment, when the number of the ring regions is one, the withstand voltage of the transistor array is improved by 20% to 50%.

In one embodiment, the transistor array comprises a plurality of Metal-Oxide-Semiconductor Field-Effect Transistors (MOSFETs).

After referring to the drawings and the embodiments as described in the following, those having ordinary skill in the art can understand other objectives of the present invention, as well as the technical means and embodiments of the present invention.

### BRIEF DESCRIPTION OF THE DRAWINGS

FIG. 1 is a schematic diagram of the integrated circuit of the present invention;

FIG. 2 is a partial cross-sectional view of the integrated circuit of the present invention;

FIG. 3 is a partial schematic diagram of the guard ring of the present invention;

FIG. 4 is a partial schematic diagram of the guard ring of the present invention;

FIG. 5 is a partial schematic diagram of the guard ring of the present invention; and

FIG. 6 is a schematic diagram of the integrated circuit of the present invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application, or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

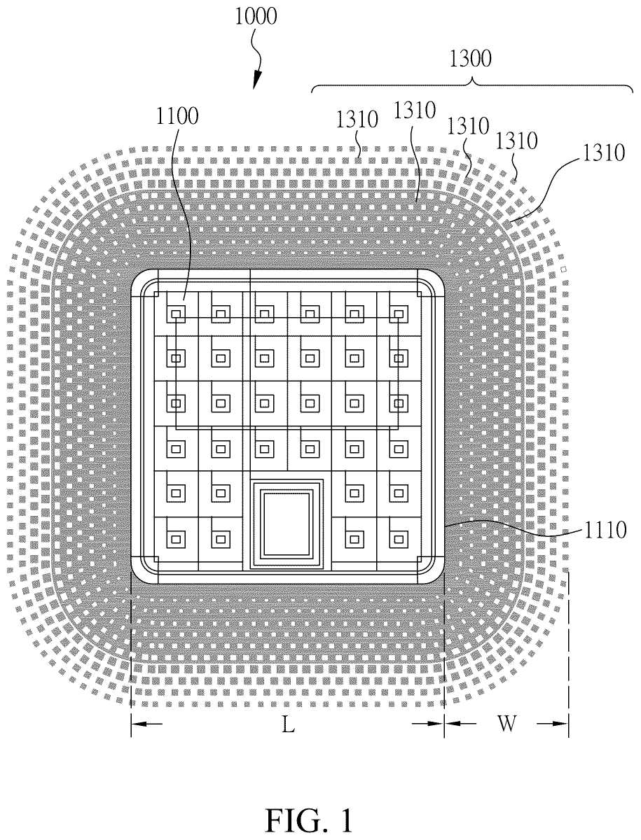

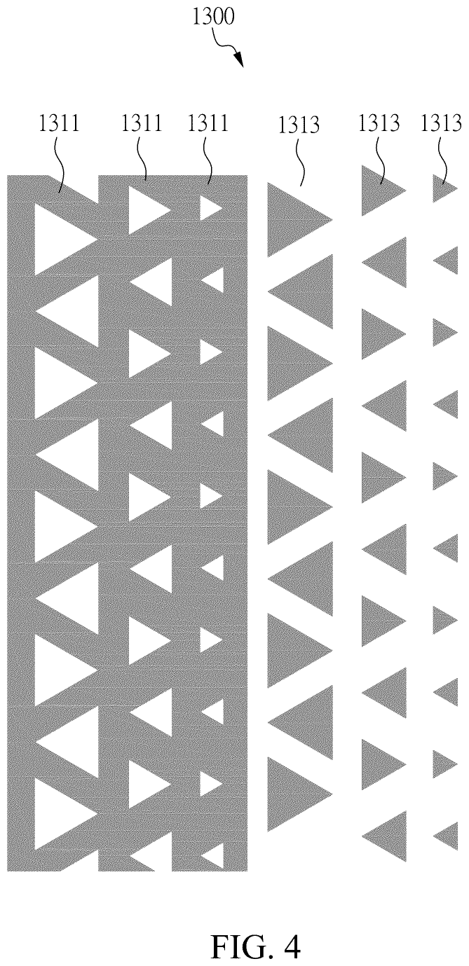

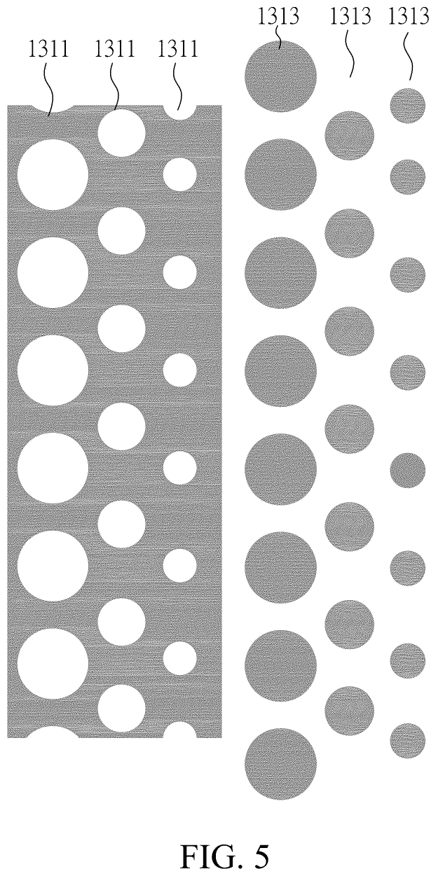

The first embodiment of the present invention is illustrated in FIG. 1 to FIG. 5. FIG. 1 depicts a schematic diagram of the integrated circuit 1000 of the present invention. The integrated circuit 1000 includes a transistor array 1100 and a guard ring 1300. The transistor array 1100 comprises a plurality of Metal-Oxide-Semiconductor Field-Effect Transistors (MOSFETs).

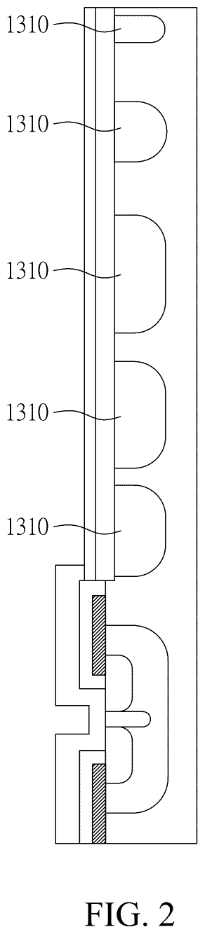

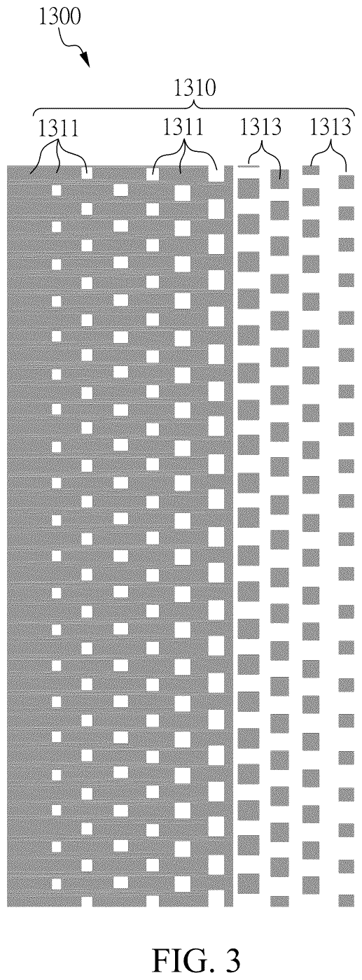

Please refer to FIG. 2 and FIG. 3. FIG. 2 illustrates a partial cross-sectional view of the integrated circuit of the present invention. FIG. 3 illustrates a partial schematic diagram of the guard ring 1300 of the present invention. The guard ring 1300 is formed on the periphery 1110 of the transistor array 1100, significantly enhancing the overall withstand voltage of the transistor array 1100.

Specifically, the guard ring 1300 comprises a plurality of ring regions 1310. The ring regions 1310 are divided into an inner part 1311 and an outer part 1313. The width of the inner part is greater than 100 micrometers (μm). The ratio of a side length L of the transistor array 1100 to a total width W of the ring regions 1310 is less than 10. The optimal ratio of the side length L of the transistor array 1100 to the total width W of the ring regions 1310 is 5:3.

Each of the ring regions 1310 has a doped area (as shown in the gray areas in FIG. 3 to FIG. 5). The doped area of an inner side of the ring regions 1310 is greater than the doped area of an outer side of the ring regions 1310.

These doped areas can be regarded as doping concentrations. Specifically, in the process of manufacturing Metal-Oxide-Semiconductor Field-Effect Transistors (MOSFETs), P-type ions, such as boron ions, aluminum ions, gallium ions, indium ions, etc., carrying positive charges are implanted into the N-type epitaxial layer to form a P-type doped area.

Each of the ring regions 1310 has P-type doped areas with different doping ratios. The inner part 1311 of the ring regions 1310 is achieved by determining the ratio of the undoped area for each of the ring region 1310 of the inner part 1311 in advance and then implanting P-type ions into the remaining part of each of the ring regions 1310 of the inner part 1311. On the other hand, the outer part 1313 of the ring regions 1310 is achieved by determining the ratio of the doped area in advance and directly implanting P-type ions into the part that is needed to be doped.

The undoped area of the inner part 1311 of the ring regions 1310 and the doped area of the outer part 1313 of the ring regions 1310 are formed by a plurality of discrete parts. The shape of each discrete part is one of a rectangle, a circle, and a polygon, as shown in FIG. 3 to FIG. 5.

In summary, the inner part 1311 of the ring regions 1310 is formed by determining the ratio of the undoped area and selecting the positions not to be doped. On the other hand, the outer part 1313 of the ring regions 1310 is formed by determining the ratio of the doped area and selecting the positions to be doped.

The doped area of the innermost side of the ring regions 1310 is equal to the total area of the innermost side of the ring regions 1310. In other words, the innermost side of the ring regions 1310 is connected to the transistor array 1100, and the doped area of the innermost side of the ring regions 1310 is 100%.

The withstand voltage of the transistor array 1100 is improved with the increase of the total width of the ring regions 1310, and the total width of the ring regions 1310 increases with the number of the ring regions 1310. Furthermore, in this embodiment, when the number of the ring regions 1310 is one, the withstand voltage of the transistor array 1100 can be improved by 20% to 50%.

When a surge current occurs in the circuit using the transistor array 1100, it can flow outward through the P-type doped areas, allowing the surge current and heat to dissipate outwards. Therefore, the integrated circuit 1000 of the present invention can enhance the real-time dispersion effects of surge currents and heat dissipation effects.

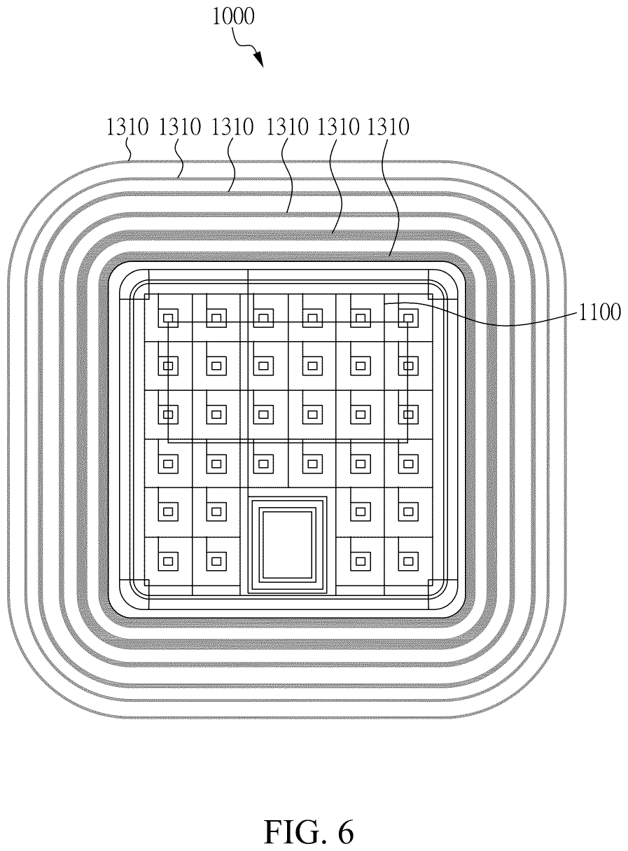

The second embodiment of the present invention is shown in FIG. 6. The second embodiment is an extension of the first embodiment. In contrast to the first embodiment, where the undoped area of the inner part 1311 and the doped area of the outer part 1313 are formed by discrete parts of arbitrary shapes, in this embodiment, the doped area of each of the ring regions 1310 has a ring shape. When the number of the ring regions 1310 is one, the withstand voltage of the transistor array 1100 can be improved by 20% to 50%.

In summary, the integrated circuit of the present invention protects against surges by placing a guard ring at the periphery of the transistor array. Each ring-shaped region within the guard ring has a specific ratio of doped to undoped areas, and the doped area decreases outward. Therefore, when a surge occurs in the integrated circuit, the guard ring disperses the surge current outward, preventing damage to the circuit and improving the overall circuit withstand voltage.

The above embodiments are used only to illustrate the implementations of the present invention and to explain the technical features of the present invention and are not used to limit the scope of the present invention. Any modifications or equivalent arrangements that can be easily accomplished by people skilled in the art are considered to fall within the scope of the present invention, and the scope of the present invention should be limited by the claims of the patent application.

What is claimed is:

1. An integrated circuit, comprising:
a transistor array; and
a guard ring, formed on a periphery of the transistor array,
wherein the guard ring includes a plurality of ring regions, each of the ring regions includes a doped area, and a doped area of an inner side of the ring regions is greater than a doped area of an outer side of the ring regions.

2. The integrated circuit of claim 1, wherein the doped area of an innermost side of the ring regions is equal to a total area of the innermost side of the ring regions.

3. The integrated circuit of claim 1, wherein a ratio of a side length of the transistor array to a total width of the ring regions is less than 10.

4. The integrated circuit of claim 3, wherein a ratio of the side length to the total width is 5:3.

5. The integrated circuit of claim 3, wherein the ring regions are divided into an inner part and an outer part, and a width of the inner part is larger than 100 micrometers (μm).

6. The integrated circuit of claim 5, wherein an undoped area of the inner part of the ring regions and the doped area of the outer part of the ring regions are formed by a plurality of discrete parts, and a shape of each of the discrete parts is one of a rectangle, a circle, and a polygon.

7. The integrated circuit of claim 6, wherein when the number of the ring regions is one, a withstand voltage of the transistor array is improved by 20% to 50%.

8. The integrated circuit of claim 3, wherein a withstand voltage of the transistor array is improved with the increase of the total width.

9. The integrated circuit of claim 1, wherein the doped area of each of the ring regions is provided with a ring shape.

10. The integrated circuit of claim 9, wherein when the number of the ring regions is one, a withstand voltage of the transistor array is improved by 20% to 50%.

11. The integrated circuit of claim 1, wherein the transistor array comprises a plurality of Metal-Oxide-Semiconductor Field-Effect Transistors (MOSFETs).
